(19) United States
(12) Patent Application Publication
(10) Pub. No.: US 2026/0323929 A1
(43) Pub. Date: Oct. 15, 2026

(54) ELECTRICAL STRUCTURE INCLUDING A MOS TRANSISTOR AND METHOD OF MANUFACTURING THE SAME

(71) Applicant: NANYA TECHNOLOGY CORPORATION, NEW TAIPEI CITY (TW)

(72) Inventors: YU-PING CHEN, NEW TAIPEI CITY (TW); CHUNG-HSUN HUANG, NEW TAIPEI CITY (TW); JHEN-YU TSAI, NEW TAIPEI CITY (TW)

(21) Appl. No.: 19/175,196

(22) Filed: Apr. 10, 2025

(51) Int. Cl. H10B 12/00

(52) U.S. Cl. CPC H10B 12/50

(57) ABSTRACT

An electrical structure and a method of manufacturing an electrical structure are provided. The electrical structure includes a substrate and a metal-oxide-semiconductor (MOS) transistor. The MOS transistor is disposed on a first surface of the substrate, and includes a gate structure. The gate structure has a top surface and a bottom surface opposite to the top surface. A width of the top surface is less than a width of the bottom surface.

### TECHNICAL FIELD

The present disclosure relates to an electrical structure and a method of manufacturing the same, and more particularly, to an electrical structure including a MOS transistor, and a method of manufacturing the same.

### DISCUSSION OF THE BACKGROUND

Semiconductor structures are used in a variety of electronic applications, and the dimensions of semiconductor structures are continuously being scaled down to meet the current application requirements. However, a variety of issues arise during the scaling-down process and impact the final electrical characteristics, quality, cost and yield. Typical memory devices (such as dynamic random access memory (DRAM) devices) include signal lines, such as word lines and bit lines crossing the word lines. As DRAM devices are scaled down and the dimensions and/or pitches of the signal lines are getting smaller, the parasitic capacitance will be a critical concern.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides an electrical structure including a substrate and a metal-oxide-semiconductor (MOS) transistor. The MOS transistor is disposed on a first surface of the substrate, and includes a gate structure. The gate structure has a top surface and a bottom surface opposite to the top surface. A width of the top surface is less than a width of the bottom surface.

Another aspect of the present disclosure provides an electrical structure including a substrate, a MOS transistor and an electrical contact. The MOS transistor is disposed on a first surface of the substrate, and includes a gate structure. The electrical contact is disposed adjacent to the MOS transistor and electrically connects the first surface of the substrate. A distance between the gate structure of the MOS transistor and the electrical contact reduces toward the first surface of the substrate.

Another aspect of the present disclosure provides a method of manufacturing an electrical structure. The method includes forming a gate structure on a first surface of a substrate. The method also includes removing a portion of the gate structure, so that a width of a top surface of the gate structure is less than a width of a bottom surface of the gate structure. The method also includes forming a spacer on a lateral surface of the gate structure.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 illustrates, in a flowchart diagram form, a method of manufacturing an electrical structure in accordance with one embodiment of the present disclosure.

FIG. 2 illustrates one stage of a method of manufacturing an electrical structure, in accordance with one embodiment of the present disclosure.

FIG. 3 illustrates one stage of a method of manufacturing an electrical structure, in accordance with one embodiment of the present disclosure.

FIG. 4 illustrates one stage of a method of manufacturing an electrical structure, in accordance with one embodiment of the present disclosure.

FIG. 5 illustrates one stage of a method of manufacturing an electrical structure, in accordance with one embodiment of the present disclosure.

FIG. 6 illustrates one stage of a method of manufacturing an electrical structure, in accordance with one embodiment of the present disclosure.

FIG. 7 illustrates one stage of a method of manufacturing an electrical structure, in accordance with one embodiment of the present disclosure.

FIG. 8 illustrates one stage of a method of manufacturing an electrical structure, in accordance with one embodiment of the present disclosure.

FIG. 9 illustrates one stage of a method of manufacturing an electrical structure, in accordance with one embodiment of the present disclosure.

FIG. 10 illustrates one stage of a method of manufacturing an electrical structure, in accordance with one embodiment of the present disclosure.

FIG. 11 illustrates one stage of a method of manufacturing an electrical structure, in accordance with one embodiment of the present disclosure.

FIG. 12 illustrates a schematic cross-sectional view of an electrical structure in accordance with one embodiment of the present disclosure.

FIG. 13 illustrates one stage of a method of manufacturing an electrical structure, in accordance with one embodiment of the present disclosure.

FIG. 14 illustrates one stage of a method of manufacturing an electrical structure, in accordance with one embodiment of the present disclosure.

FIG. 15 illustrates one stage of a method of manufacturing an electrical structure, in accordance with one embodiment of the present disclosure.

FIG. 16 illustrates one stage of a method of manufacturing an electrical structure, in accordance with one embodiment of the present disclosure.

FIG. 17 illustrates a schematic cross-sectional view of an electrical structure in accordance with one embodiment of the present disclosure.

FIG. 18 illustrates a schematic cross-sectional view of an electrical structure in accordance with one embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

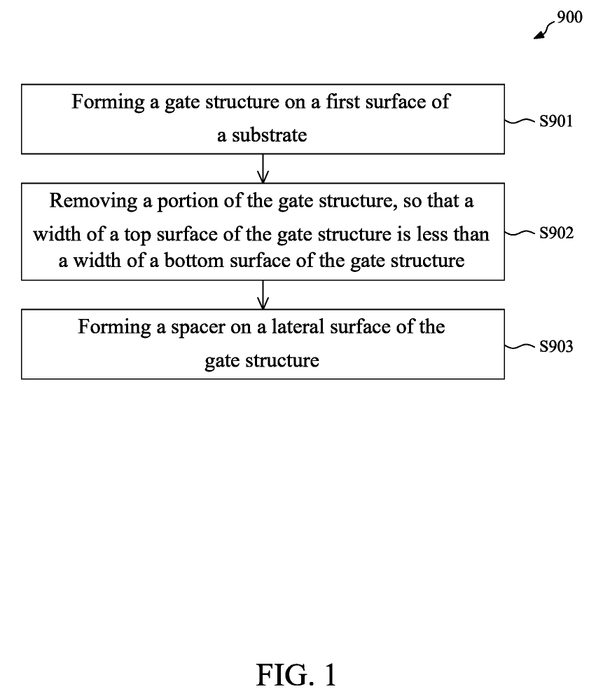

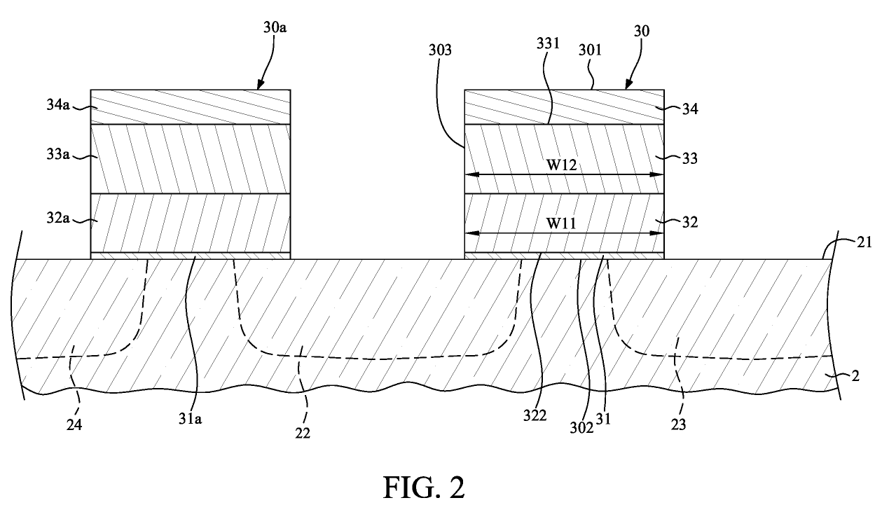

FIG. 1 illustrates, in a flowchart diagram form, a method 900 for manufacturing an electrical structure 1 in accordance with one embodiment of the present disclosure. FIG. 2 to FIG. 12 illustrate stages of a method for manufacturing an electrical structure 1 in accordance with one embodiment of the present disclosure. At least some of these figures have been simplified for a better understanding of the aspects of the present disclosure.

Referring to FIG. 1 and FIG. 2, at step S901, forming a gate structure (including a first gate structure 30 and a second gate structure 30a) on a first surface 21 of a substrate 2.

In some embodiments, the substrate 2 may have a first surface 21 (e.g., a top surface). The substrate 2 may include a drain electrode 22, a source electrode 23 and a source electrode 24. The substrate 2 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

The first gate structure 30 may include a gate oxide layer 31, a first gate conductor layer 32, a second gate conductor layer 33 and an upper layer 34. The formation of the first gate structure 30 may include the following steps. First, the gate oxide layer 31 may be formed or disposed on the first surface 21 of the substrate 2, and may include an oxide material for electrical insulation. The gate oxide layer 31 may have a substantially constant width.

Then, the first gate conductor layer 32 may be formed or disposed on the gate oxide layer 31, and may include a polysilicon material. Thus, the first gate conductor layer 32 may be formed or disposed over the first surface 21 of the substrate 2. The first gate conductor layer 32 may have a first width W11. The first width W11 may be substantially constant. Thus, the cross-sectional view of the first gate conductor layer 32 may be in a rectangular shape.

Then, the second gate conductor layer 33 may be formed or disposed on the first gate conductor layer 32, and may include a tungsten silicide (WSix) material. The second gate conductor layer 33 may have a second width W12. The second width W12 may be substantially constant. Thus, the cross-sectional view of the second gate conductor layer 33 may be in a rectangular shape. The second width W12 of the second gate conductor layer 33 may be substantially equal to the first width W11 of the first gate conductor layer 32.

Then, the upper layer 34 may be formed or disposed on the second gate conductor layer 33, and may include a nitride material. The upper layer 34 may have a substantially constant width. Thus, the cross-sectional view of the upper layer 34 may be in a rectangular shape. The substantially constant width of the upper layer 34 may be substantially equal to the second width W12 of the second gate conductor layer 33.

The first gate structure 30 may have a top surface 301, a bottom surface 302 opposite to the top surface 301 and a lateral surface 303 extending between the top surface 301 and the bottom surface 302. The bottom surface 302 of the first gate structure 30 may contact the first surface 21 of the substrate 2. A top surface 301 of the upper layer 34 may be the top surface 301 of the first gate structure 30. A bottom surface 302 of the gate oxide layer 31 may be the bottom surface 302 of the first gate structure 30.

In some embodiments, the first gate conductor layer 32 and the second gate conductor layer 33 may be collectively defined as a gate electrode of a gate contact. A top surface 331 of the second gate conductor layer 33 may be the top surface 331 of the gate electrode (including the first gate conductor layer 32 and the second gate conductor layer 33). A bottom surface 322 of the first gate conductor layer 32 may be the bottom surface 322 of the gate electrode (including the first gate conductor layer 32 and the second gate conductor layer 33).

The second gate structure 30a may include a gate oxide layer 31a, a first gate conductor layer 32a, a second gate conductor layer 33a and an upper layer 34a. The structure of the second gate structure 30a may be the same as the structure of the first gate structure 30. That is, the size and the material of the gate oxide layer 31a, the first gate conductor layer 32a, the second gate conductor layer 33a and the upper layer 34a of the second gate structure 30a may be the same as the size and the material of the gate oxide layer 31, the first gate conductor layer 32, the second gate conductor layer 33 and the upper layer 34 of the first gate structure 30, respectively.

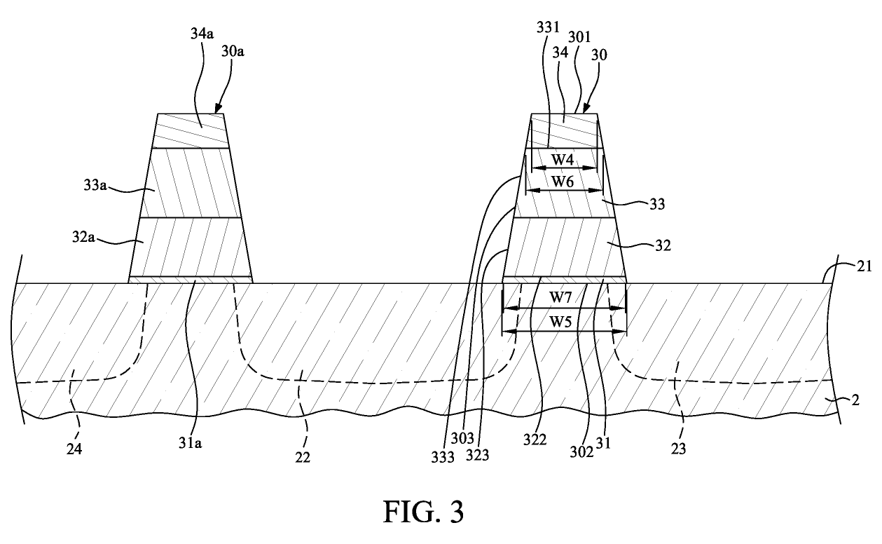

Referring to FIG. 1 and FIG. 3, at step S902, removing a portion of the gate structure (e.g., the first gate structure 30), so that a width W4 of the top surface 301 of the gate structure (e.g., the first gate structure 30) may be less than a width W5 of the bottom surface 302 of the gate structure (e.g., the first gate structure 30).

A portion of the second gate conductor layer 33 and a portion of the first gate conductor layer 32 may be removed simultaneously by, for example, etching. The second gate conductor layer 33 and the first gate conductor layer 32 may be etched at different etching rates. Alternatively, the second gate conductor layer 33 and the first gate conductor layer 32 may be etched at a specific selective etching ratio. Thus, both of the first gate conductor layer 32 and the second gate conductor layer 33 may taper away from the first surface 21 of the substrate 2. Both of the first gate conductor layer 32 and the second gate conductor layer 33 may taper upward.

Each of the first gate conductor layer 32 and the second gate conductor layer 33 may be in a trapezoid shape. The lateral surface 323 of the first gate conductor layer 32 may be aligned with the lateral surface 333 of the second gate conductor layer 33. In the gate electrode (including the first gate conductor layer 32 and the second gate conductor layer 33), a width W6 of a top surface 331 of the second gate conductor layer 33 is less than a width W7 of a bottom surface 322 of the first gate conductor layer 32. The width W6 of the top surface 331 of the second gate conductor layer 33 of FIG. 3 may be less than the second width W12 of FIG. 2. The width W7 of the bottom surface 322 of the first gate conductor layer 32 of FIG. 3 may be less than the first width W11 of FIG. 2.

Meanwhile, a portion of the gate oxide layer 31 and a portion of the upper layer 34 may be removed simultaneously with the second gate conductor layer 33 and the first gate conductor layer 32 by, for example, etching. The upper layer 34, the second gate conductor layer 33, the first gate conductor layer 32 and the gate oxide layer 31 may be etched at different etching rates. Alternatively, the upper layer 34, the second gate conductor layer 33, the first gate conductor layer 32 and the gate oxide layer 31 may be etched at a specific selective etching ratio. Thus, both of the upper layer 34 and the gate oxide layer 31 may taper away from the first surface 21 of the substrate 2. Both of the upper layer 34 and the gate oxide layer 31 may taper upward.

Each of the upper layer 34 and the gate oxide layer 31 may be in a trapezoid shape. The lateral surface of the upper layer 34 may be substantially aligned with the lateral surface 333 of the second gate conductor layer 33, the lateral surface 323 of the first gate conductor layer 32 and the lateral surface of the gate oxide layer 31. As a result, the width W4 of the top surface 301 of the first gate structure 30 may be less than the width W5 of the bottom surface 302 of the first gate structure 30. The first gate structure 30 may be in a trapezoid shape.

The first gate structure 30 may taper away from the first surface 21 of the substrate 2. The first gate structure 30 may taper upward. In some embodiments, a ratio of the width W4 of the top surface 301 of the first gate structure 30 to the width W5 of the bottom surface 302 of the first gate structure 30 may be 1/4 to 1/2, or 1/4 to 3/4, or 1/3 to 2/3. The entire lateral surface 303 of the first gate structure 30 may be a flat inclined surface. An inclination angle between the lateral surface 303 of the first gate structure 30 and the first surface 21 of the substrate 2 may be less than 90 degrees.

Similarly, the second gate structure 30a may be also etched. Thus, the profile of the second gate structure 30a may be the same as the profile of the first gate structure 30.

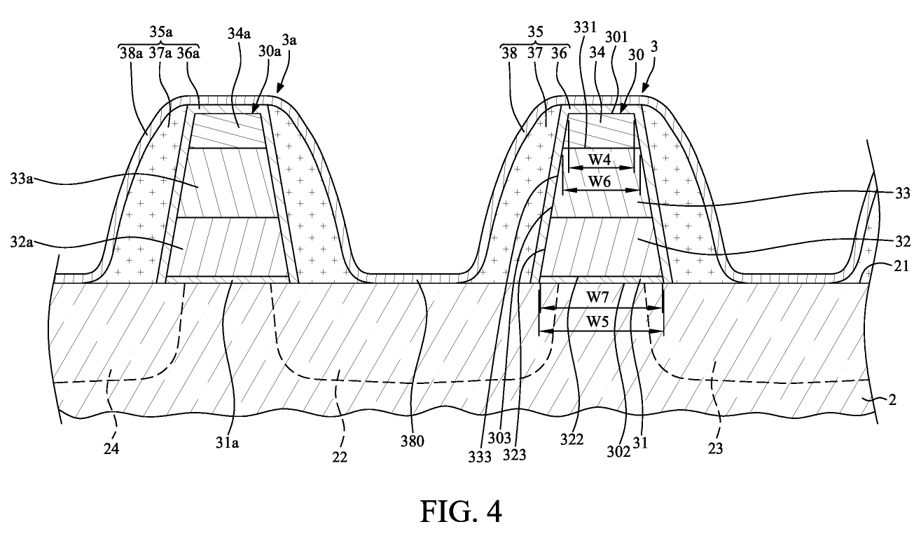

Referring to FIG. 1 and FIG. 4, at step S903, forming a spacer (e.g., a first spacer 35 or a second spacer 35a) on the lateral surface 303 of the gate structure (e.g., the first gate structure 30 or the second gate structure 30a). The formation of the first spacer 35 and the second spacer 35a may include the following steps. First, a first layer 36 may be conformally formed or disposed on the lateral surface 303 of the first gate structure 30. A first layer 36a may be conformally formed or disposed on the lateral surface of the second gate structure 30a. A material of the first layers 36, 36a may include a nitride material. Then, a second layer 37 may be formed or disposed on a lateral surface of the first layer 36 and on a portion of the first surface 21 of the substrate 2. A second layer 37a may be formed or disposed on a lateral surface of the first layer 36a and on a portion of the first surface 21 of the substrate 2. The second layers 37, 37a may taper upward, and may include an oxide material.

Then, a protection layer 380 may be formed on the first layers 36, 36a and the second layers 37, 37a by, for example, deposition. The protection layer 380 may include a nitride material. The protection layer 380 may include a third layer 38 on the second layer 37 of the first spacer 35, and a third layer 38a on the second layer 37a of the second spacer 35a. Thus, the first spacer 35 may include the first layer 36, the second layer 37 and the third layer 38. The second spacer 35a may include the first layer 36a, the second layer 37a and the third layer 38a. Meanwhile, a first MOS transistor 3 and a second MOS transistor 3a may be formed and may be separated from each other. The first MOS transistor 3 may include the first gate structure 30 and the first spacer 35 disposed on the lateral surface 303 of the first gate structure 30. The second MOS transistor 3a may include the second gate structure 30a and the second spacer 35a disposed on the lateral surface of the second gate structure 30a.

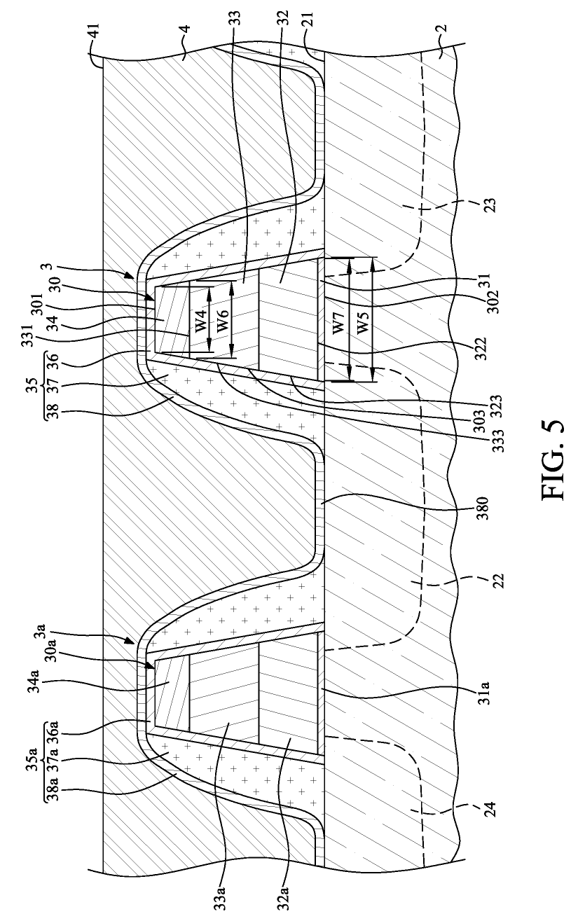

Referring to FIG. 5, a first insulation layer 4 may be formed or disposed over the first surface 21 of the substrate 2. In some embodiments, the first insulation layer 4 may be disposed on the first surface 21 of the substrate 2, and may cover the first MOS transistor 3 (including the first gate structure 30 and the first spacer 35) and the second MOS transistor 3a (including the second gate structure 30a and the second spacer 35a). A first surface 41 (e.g., a top surface) of the first insulation layer 4 may be higher than a top surface of the third layer 38 of the first MOS transistor 3 and a top surface of the third layer 38a of the second MOS transistor 3a. The first insulation layer 4 may include an oxide material such as silicon dioxide (SiO₂).

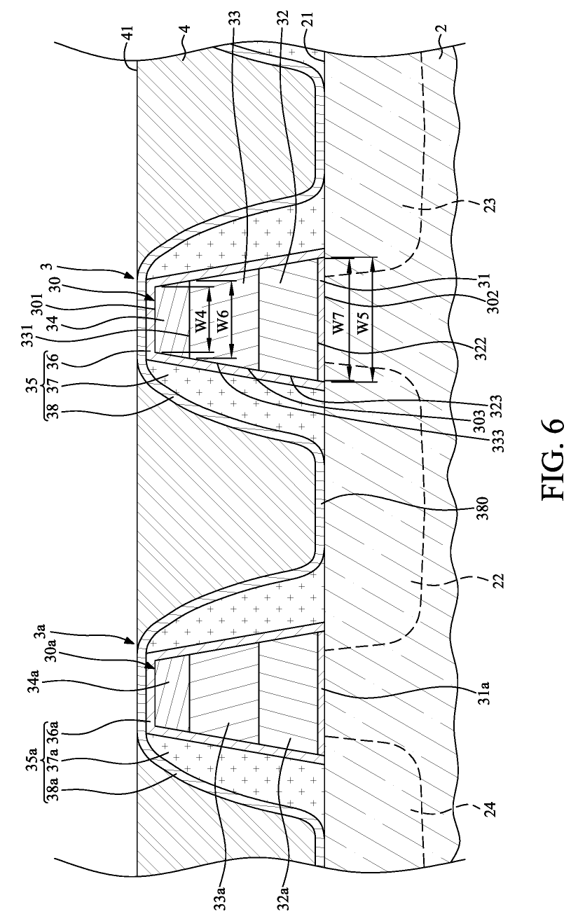

Referring to FIG. 6, the first insulation layer 4 may be thinned from the first surface 41 by, for example, grinding. Thus, an upper portion of the first insulation layer 4 may be removed, and the first surface 41 of the first insulation layer 4 may be aligned with the top surface of the third layer 38 of the first MOS transistor 3 and the top surface of the third layer 38a of the second MOS transistor 3a. Thus, the top surface of the third layer 38 of the first MOS transistor 3 and the top surface of the third layer 38a of the second MOS transistor 3a may be exposed from the first surface 41 of the first insulation layer 4.

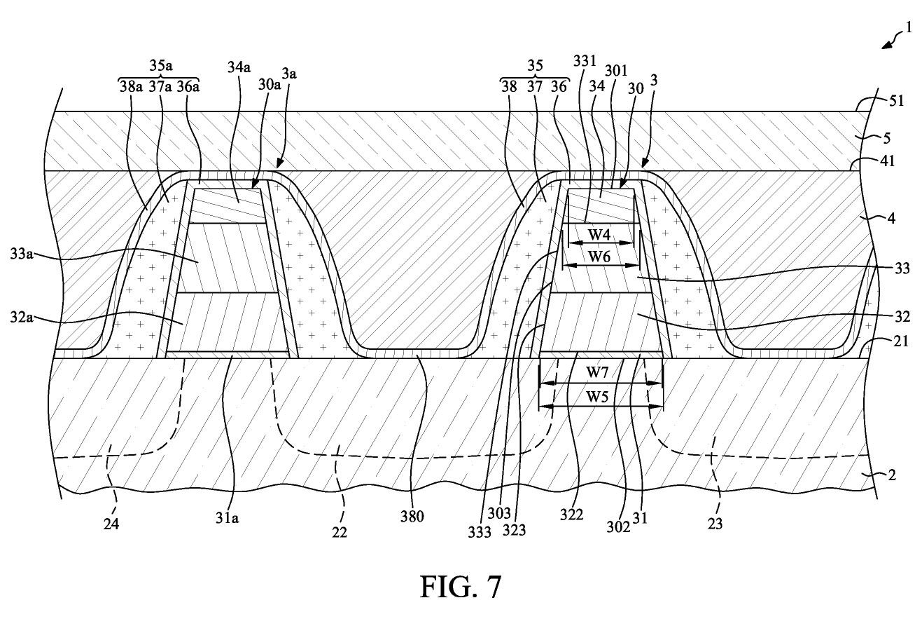

Referring to FIG. 7, a second insulation layer 5 may be formed or disposed on the first insulation layer 4. The second insulation layer 5 may cover and contact the first surface 41 of the first insulation layer 4. A material of the second insulation layer 5 may be different from a material of the first insulation layer 4. The second insulation layer 5 may include a nitride material such as silicon nitride (Si₃N₄, or SiN).

Meanwhile, an electrical structure 1 (or a stacked structure or a semiconductor structure) may be formed.

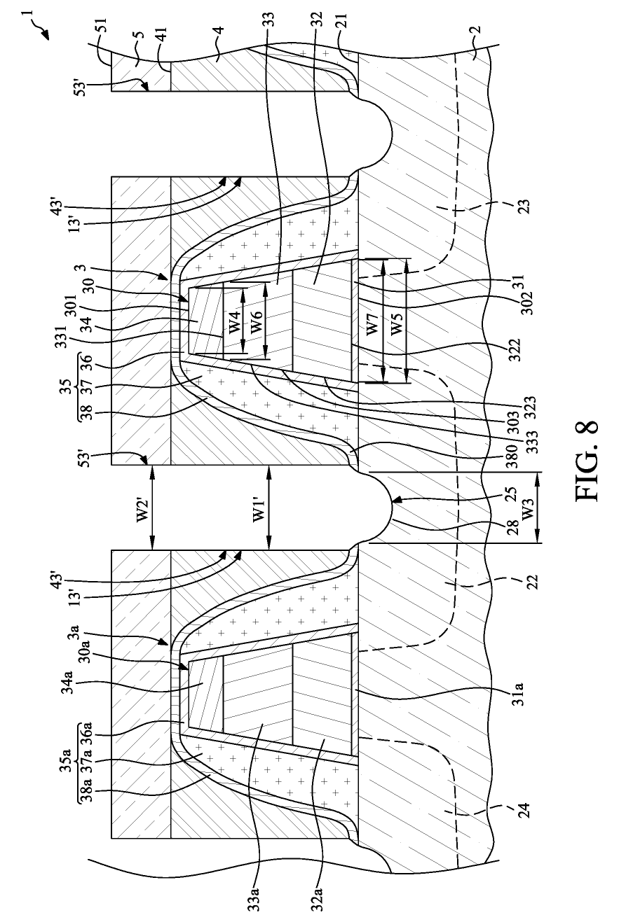

Referring to FIG. 8, at least one first hole structure 13' may be formed from the first surface 51 of the second insulation layer 5 to expose a portion 28 of the substrate 2 by, for example, dry etching. The first hole structure 13' may extend through the first insulation layer 4 to form a through hole 43' having a width W1'. The first hole structure 13' may extend through the second insulation layer 5 to form a through hole 53' having a width W2'. The width W1' may be substantially equal to the width W2'. The first hole structure(s) 13' may be disposed at two sides of the first MOS transistor 3. For example, a first hole structure 13' may be disposed between the first MOS transistor 3 and the second MOS transistor 3a.

In some embodiments, the first hole structure 13' may further extend through the protection layer 380 and extend into the substrate 2 to form a recess portion 25 recessed from the first surface 21 of the substrate 2. The recess portion 25 has a width W3. The width W3 may be the maximum width of the recess portion 25, and may be less than the width W1'.

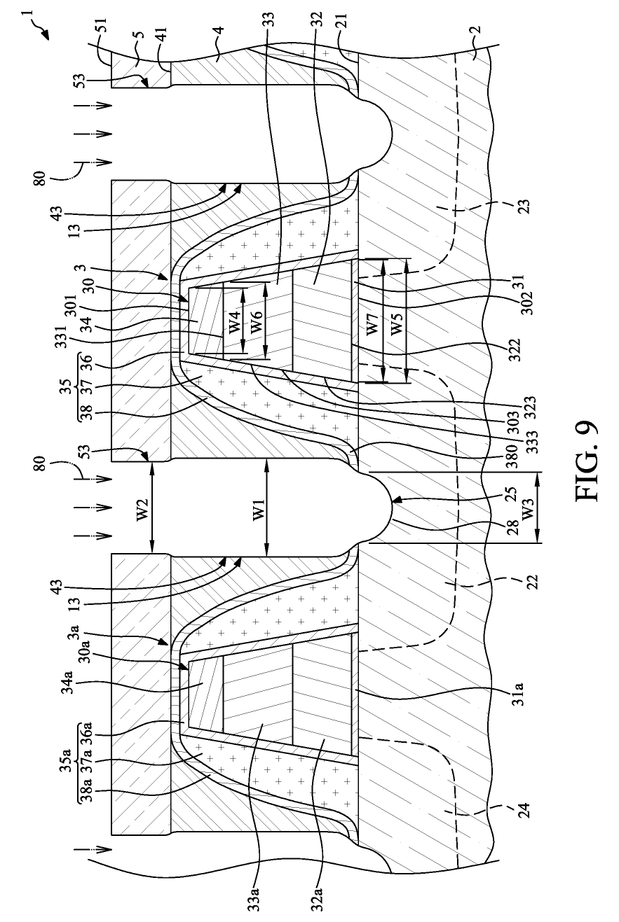

Referring to FIG. 9, the exposed portion 28 of the substrate 2 may be cleaned through a cleaning agent 80 applied into the first hole structure 13'. Meanwhile, the cleaning agent 80 may etch the first insulation layer 4 and the second insulation layer 5 so as to enlarge the first hole structure 13' to become a second hole structure 13. Thus, the second hole structure 13 may be formed by, for example, wet etching. The cleaning agent 80 may include water and hydrofluoric acid (HF), and a weight ratio of water to HF may be between 500:1 and 2500:1. The weight ratio of water to HF may be between 1800:1 and 2200:1, between 1000:1 and 2000:1, or between 1500:1 and 2100:1. Such cleaning agent 80 may be also referred to as an "ultra dilute hydrofluoric acid (HF)".

The second hole structure 13 may extend through the first insulation layer 4 to form a first through hole 43 (or first enlarged through hole) having a first width W1. The second hole structure 13 may extend through the second insulation layer 5 to form a second through hole 53 (or second enlarged through hole) having a second width W2. The first width W1 may be greater than the second width W2 since an etching rate of the cleaning agent 80 to the first insulation layer 4 is greater than an etching rate of the cleaning agent 80 to the second insulation layer 5.

In some embodiments, a difference between the first width W1 and the second width W2 may be less than one tenth of the first width W1. That is, a ratio of (W1-W2)/W1 may be less than 0.1, 0.09, 0.08, 0.07 or 0.06. Therefore, a gap (or a tolerance) between a sidewall of the first through hole 43 and a sidewall of the second through hole 53 may be very small. The sidewall of the first through hole 43 and the sidewall of the second through hole 53 may be approximately aligned with each other.

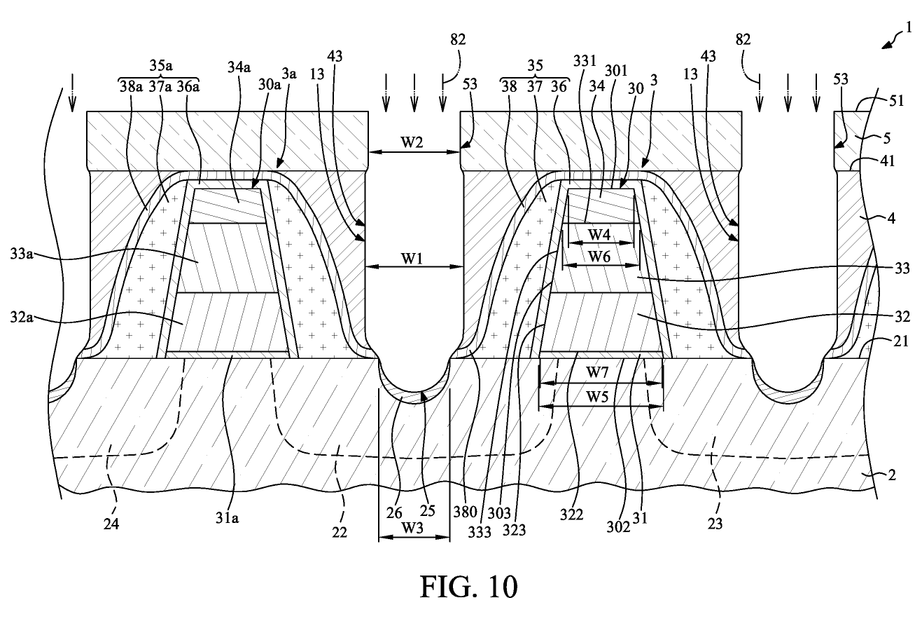

Referring to FIG. 10, a low resistance layer 26 may be formed on the cleaned exposed portion 28 of the substrate 2 by, for example, sputtering and annealing. In some embodiments, the low resistance layer 26 may be formed by sputtering cobalt (Co) 82 and then annealing, so that the low resistance layer 26 may include cobalt disilicide (CoSi₂). In the present disclosure, the ultra-dilute hydrofluoric acid (HF) as stated above may not influence the formation of the low resistance layer 26. Then, the residual cobalt (Co) may be removed by, for example, wet cleaning.

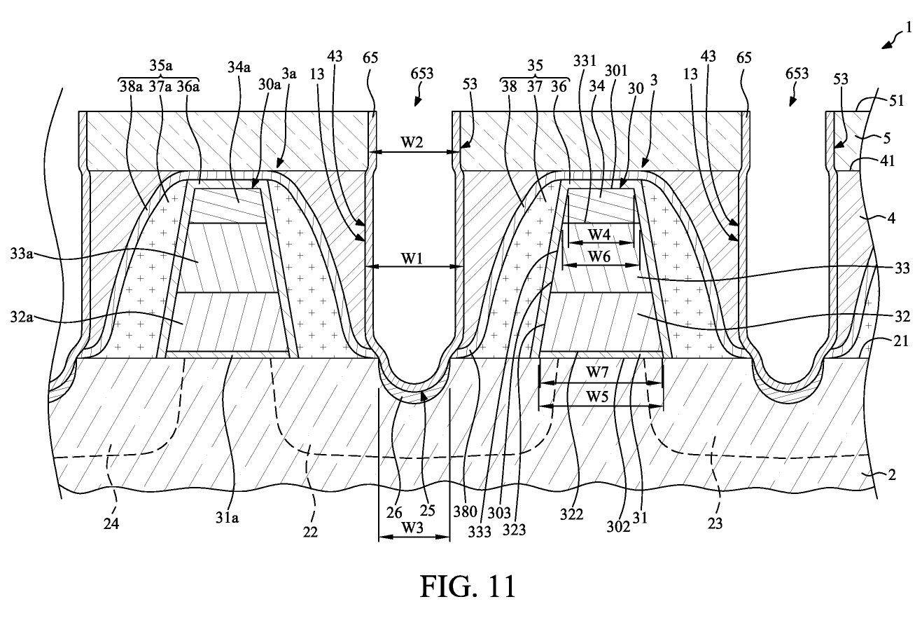

Referring to FIG. 11, a periphery layer 65 may be formed or disposed on a sidewall of the second hole structure 13 by, for example, deposition. The periphery layer 65 may define a central hole 653. The periphery layer 65 may include titanium nitride (TiN). As shown in FIG. 11, the difference between the first width W1 of the first through hole 43 and the second width W2 of the second through hole 53 may be reduced. Thus, the sidewall of the second hole structure 13 may be substantially straight so as to facilitate the deposition process of the periphery layer 65.

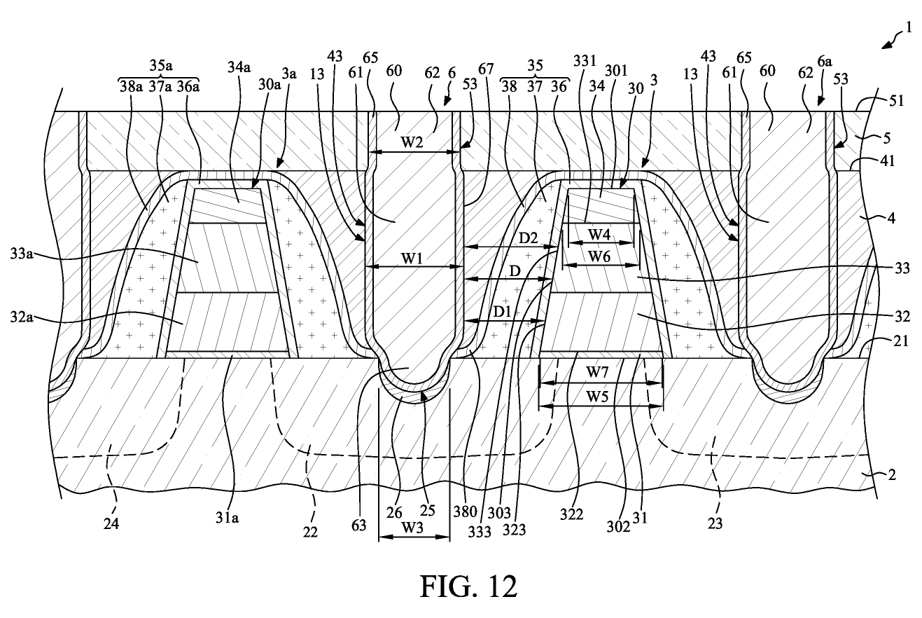

Referring to FIG. 12, a central material 60 may fill the central hole 653 defined by the periphery layer 65 so as to form an electrical contact 6 and an electrical contact 6a. The central material 60 may include tungsten (W). The electrical contact 6 and the electrical contact 6a may extend through the second insulation layer 5 and the first insulation layer 4.

FIG. 12 illustrates a schematic cross-sectional view of an electrical structure 1 in accordance with one embodiment of the present disclosure. In some embodiments, the electrical structure 1 may be a semiconductor structure or a semiconductor device that includes a circuit, such as a memory cell. In some embodiments, the memory cell may include a dynamic random access memory cell (DRAM cell).

In addition, the electrical structure 1 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The electrical structure 1 may include a substrate 2, a first MOS transistor 3, a second MOS transistor 3a, a first insulation layer 4, a second insulation layer 5, an electrical contact 6 and an electrical contact 6a.

In some embodiments, the substrate 2 may have a first surface 21 (e.g., a top surface). The substrate 2 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some other embodiments, the substrate 2 may include a semiconductor-on-insulator substrate, such as a silicon-on-insulator (SOI) substrate, a silicon germanium-on-insulator (SGOI) substrate, or a germanium-on-insulator (GOI) substrate.

Depending on the IC fabrication stage, the substrate 2 may include various material layers (e.g., dielectric layers, semiconductor layers, and/or conductive layers) configured to form IC features (e.g., doped regions, isolation features, gate features, source/drain features, interconnect features, other features, or combinations thereof).

As shown in FIG. 12, the substrate 2 may include a drain electrode 22, a source electrode 23 and a source electrode 24. The substrate 2 may define a recess portion 25 recessed from the first surface 21 (e.g., the top surface) of the substrate 2. The recess portion 25 may be disposed in the drain electrode 22 or the source electrode 23. The recess portion 25 has a third width W3. The third width W3 may be the maximum width of the recess portion 25. In addition, the substrate 2 may include a low resistance layer 26 disposed on a bottom wall of the recess portion 25. The low resistance layer 26 may include cobalt (Co) such as cobalt disilicide (CoSi₂).

The first MOS transistor 3 and the second MOS transistor 3a may be a portion of a word line. The first MOS transistor 3 and the second MOS transistor 3a may be disposed on the first surface 21 of the substrate 2. The first MOS transistor 3 may correspond to the drain electrode 22 and the source electrode 23. The first MOS transistor 3 may include a first gate structure 30 and a first spacer 35 on the first gate structure 30. The first gate structure 30 may include a gate oxide layer 31, a first gate conductor layer 32, a second gate conductor layer 33 and an upper layer 34. The gate oxide layer 31 may be formed or disposed on the first surface 21 of the substrate 2, and may include an oxide material for electrical insulation. The first gate conductor layer 32 may be formed or disposed on the gate oxide layer 31, and may include a polysilicon material. The second gate conductor layer 33 may be formed or disposed on the first gate conductor layer 32, and may include a tungsten silicide (WSix) material. The first gate conductor layer 32 and the second gate conductor layer 33 may be collectively defined as a gate electrode or a gate contact. The upper layer 34 may be disposed on the second gate conductor layer 33, and may include a nitride material. In some embodiments, the gate electrode may include the upper layer 34.

The first gate structure 30 may have a top surface 301, a bottom surface 302 opposite to the top surface 301 and a lateral surface 303 extending between the top surface 301 and the bottom surface 302. The bottom surface 302 of the first gate structure 30 may contact the first surface 21 of the substrate 2. A top surface 301 of the upper layer 34 may be the top surface 301 of the first gate structure 30. A bottom surface 302 of the gate oxide layer 31 may be the bottom surface 302 of the first gate structure 30. In addition, a top surface 331 of the second gate conductor layer 33 may be the top surface 331 of the gate electrode (including the first gate conductor layer 32 and the second gate conductor layer 33). A bottom surface 322 of the first gate conductor layer 32 may be the bottom surface 322 of the gate electrode (including the first gate conductor layer 32 and the second gate conductor layer 33).

Both of the first gate conductor layer 32 and the second gate conductor layer 33 may taper away from the first surface 21 of the substrate 2. Both of the first gate conductor layer 32 and the second gate conductor layer 33 may taper upward. Each of the first gate conductor layer 32 and the second gate conductor layer 33 may be in a trapezoid shape. The lateral surface 323 of the first gate conductor layer 32 may be aligned with the lateral surface 333 of the second gate conductor layer 33. In the gate electrode (including the first gate conductor layer 32 and the second gate conductor layer 33), a width W6 of a top surface 331 of the second gate conductor layer 33 may be less than a width W7 of a bottom surface 322 of the first gate conductor layer 32.

In addition, both of the upper layer 34 and the gate oxide layer 31 may taper away from the first surface 21 of the substrate 2. Both of the upper layer 34 and the gate oxide layer 31 may taper upward. Each of the upper layer 34 and the gate oxide layer 31 may be in a trapezoid shape. The lateral surface of the upper layer 34 may be substantially aligned with the lateral surface 333 of the second gate conductor layer 33, the lateral surface 323 of the first gate conductor layer 32 and the lateral surface of the gate oxide layer 31. As a result, the width W4 of the top surface 301 of the first gate structure 30 may be less than the width W5 of the bottom surface 302 of the first gate structure 30. The first gate structure 30 may be in a trapezoid shape.

The first gate structure 30 may taper away from the first surface 21 of the substrate 2. The first gate structure 30 may taper upward. In some embodiments, a ratio of the width W4 of the top surface 301 of the first gate structure 30 to the width W5 of the bottom surface 302 of the first gate structure 30 may be 1/4 to 1/2, or 1/4 to 3/4, or 1/3 to 2/3. The entire lateral surface 303 of the first gate structure 30 may be a flat inclined surface. An inclination angle between the lateral surface 303 of the first gate structure 30 and the first surface 21 of the substrate 2 may be less than 90 degrees.

The first spacer 35 may include a first layer 36, a second layer 37 disposed on the first layer 36 and a third layer 38 disposed on the second layer 37. The first layer 36 may cover the lateral surface 303 of the first gate structure 30. A material of the first layer 36 may include a nitride material. The second layer 37 may be formed or disposed on the first layer 36. The second layer 37 may include an oxide material. The third layer 38 may cover the first layer 36 and the second layer 37. For example, the third layer 38 may cover the outer surface of the second layer 37 and the top surface of the first layer 36. Thus, the second layer 37 may be sandwiched between the first layer 36 and the third layer 38. A bottom end of the third layer 38 may be disposed on the first surface 21 of the substrate 2.

The second MOS transistor 3a may correspond to the drain electrode 22 and the source electrode 24. The second MOS transistor 3a may include a second gate structure 30a and a second spacer 35a on the second gate structure 30a. The second gate structure 30a may include a gate oxide layer 31a, a first gate conductor layer 32a, a second gate conductor layer 33a and an upper layer 34a. The structure of the second gate structure 30a may be the same as the structure of the first gate structure 30. That is, the size and the material of the gate oxide layer 31a, the first gate conductor layer 32a, the second gate conductor layer 33a and the upper layer 34a of the second gate structure 30a may be the same as the size and the material of the gate oxide layer 31, the first gate conductor layer 32, the second gate conductor layer 33 and the upper layer 34 of the first gate structure 30, respectively.

The second spacer 35a may include a first layer 36a, a second layer 37a disposed on the first layer 36a and a third layer 38a disposed on the second layer 37a. The first layer 36a may cover the lateral surface of the second gate structure 30a. A material of the first layer 36a may include a nitride material. The second layer 37a may be formed or disposed on the first layer 36a. The second layer 37a may include an oxide material. The third layer 38a may cover the first layer 36a and the second layer 37a. For example, the third layer 38a may cover the outer surface of the second layer 37a and the top surface of the first layer 36a. Thus, the second layer 37a may be sandwiched between the first layer 36a and the third layer 38a. A bottom end of the third layer 38a may be disposed on the first surface 21 of the substrate 2.

The first insulation layer 4 may be disposed over the first surface 21 of the substrate 2. In some embodiments, the first insulation layer 4 may be disposed on the first surface 21 of the substrate 2, and may cover the first MOS transistor 3 and the second MOS transistor 3a. The first insulation layer 4 may include an oxide material such as silicon dioxide (SiO₂). A first surface 41 (e.g., a top surface) of the first insulation layer 4 may be aligned with a top surface of the third layer 38 of the first MOS transistor 3 and a top surface of the third layer 38a of the second MOS transistor 3a.

The first insulation layer 4 may define a first through hole 43 extending through the first insulation layer 4. The first through hole 43 has a width W1. The width W1 may be the maximum width of the first through hole 43. The recess portion 25 of the substrate 2 may be in communication with the first through hole 43 of the first insulation layer 4. The width W3 of the recess portion 25 may be less than the width W1 of the first through hole 43.

The second insulation layer 5 may be disposed on the first insulation layer 4. The second insulation layer 5 may cover and contact the first surface 41 of the first insulation layer 4. A material of the second insulation layer 5 may be different from a material of the first insulation layer 4. The second insulation layer 5 may include a nitride material such as silicon nitride (Si₃N₄, or SiN). The second insulation layer 5 may define a second through hole 53 extending through the second insulation layer 5. The second through hole 53 of the second insulation layer 5 may be communicated with the first through hole 43 of the first insulation layer 4 so as to form a hole structure 13 (or a contact hole). A central axis of the first through hole 43 may be substantially aligned with a central axis of the second through hole 53. Thus, the hole structure 13 may extend through the first insulation layer 4 and the second insulation layer 5, and may include the first through hole 43 and the second through hole 53. In some embodiments, the hole structure 13 may further extend into the substrate 2, and may include the recess portion 25.

The second through hole 53 has a width W2. The width W2 may be the maximum width of the second through hole 53. The width W2 of the second through hole 53 may be less than the width W1 of the first through hole 43. The width W3 of the recess portion 25 may be less than the width W2 of the second through hole 53.

The electrical contact 6 may be disposed in the hole structure 13, and may extend through the first insulation layer 4 and the second insulation layer 5 to electrically connect the first surface 21 of the substrate 2. In addition, the electrical contact 6 may further extend into the substrate 2. The electrical contact 6 may include a periphery layer 65 and a central material 60. The periphery layer 65 may be disposed on a sidewall of the hole structure 13, and may define a central hole. The central material 60 may fill the central hole defined by the periphery layer 65. The periphery layer 65 may include titanium nitride (TiN), and the central material 60 may include tungsten (W).

The electrical contact 6 may include a first portion 61, a second portion 62 and a third portion 63. The first portion 61 may be disposed in the first through hole 43 of the first insulation layer 4, and may have a width W1. It is noted that the width W1 of the first portion 61 may be a maximum width of the first portion 61, and may be substantially equal to the width W1 of the first through hole 43 of the first insulation layer 4. The first portion 61 may include a portion of the periphery layer 65 and a portion of the central material 60.

The second portion 62 may be disposed in the second through hole 53 of the second insulation layer 5, and may have a width W2. It is noted that the width W2 of the second portion 62 may be a maximum width of the second portion 62, and may be substantially equal to the width W2 of the second through hole 53 of the second insulation layer 5. The second portion 62 may include a portion of the periphery layer 65 and a portion of the central material 60. A ratio of a difference between the width W1 and the width W2 to the width W1 may be less than 10%. That is, a ratio of (W1-W2)/W1 may be less than 10%, 9%, 8%, 7% or 6%. Therefore, a gap (or a tolerance) between a sidewall of the first portion 61 and a sidewall of the second portion 62 may be very small. The sidewall of the first portion 61 and the sidewall of the second portion 62 may be approximately aligned with each other.

The third portion 63 may be disposed in the recess portion 25 of the substrate 2, and may have a width W3. It is noted that the width W3 of the third portion 63 may be a maximum width of the third portion 63, and may be substantially equal to the width W3 of the recess portion 25 of the substrate 2. The third portion 63 may include a portion of the periphery layer 65 and a portion of the central material 60. The width W3 may be less than the width W1 and the width W2. The low resistance layer 26 may be substantially conformal with the third portion 63 of the electrical contact 6.

The first portion 61, the second portion 62 and the third portion 63 of the electrical contact 6 may be formed integrally and concurrently so that the electrical contact 6 may be a monolithic structure. The electrical contact 6 may be disposed between the first MOS transistor 3 and the second MOS transistor 3a. The electrical contact 6 may electrically connect an electrode of the first MOS transistor 3 and/or the second MOS transistor 3a. In some embodiments, the low resistance layer 26 may be disposed between the electrical contact 6 and the drain electrode 22 of the substrate 2 so as to reduce the electrical resistance of ohmic contact between the electrical contact 6 and the substrate 2.

The structure of the electrical contact 6a may be the same as the structure of the electrical contact 6.

As shown in FIG. 12, a distance D between the first gate structure 30 of the first MOS transistor 3 and the electrical contact 6 may reduce toward the first surface 21 of the substrate 2. For example, the distance D between the lateral surface 303 of the first gate structure 30 of the first MOS transistor 3 and the lateral surface 67 of the electrical contact 6 may gradually reduce toward the first surface 21 of the substrate 2. A distance D2 between the lateral surface 333 of the second gate conductor layer 33 and the lateral surface 67 of the electrical contact 6 may be greater than a distance D1 between the lateral surface 323 of the first gate conductor layer 32 and the lateral surface 67 of the electrical contact 6. Thus, a width of an insulation material between the lateral surface 333 of the second gate conductor layer 33 and the lateral surface 67 of the electrical contact 6 is greater than a width of an insulation material between the lateral surface 323 of the first gate conductor layer 32 and the lateral surface 67 of the electrical contact 6. As a result, a parasitic capacitance between the first MOS transistor 3 and the electrical contact 6 may be reduced.

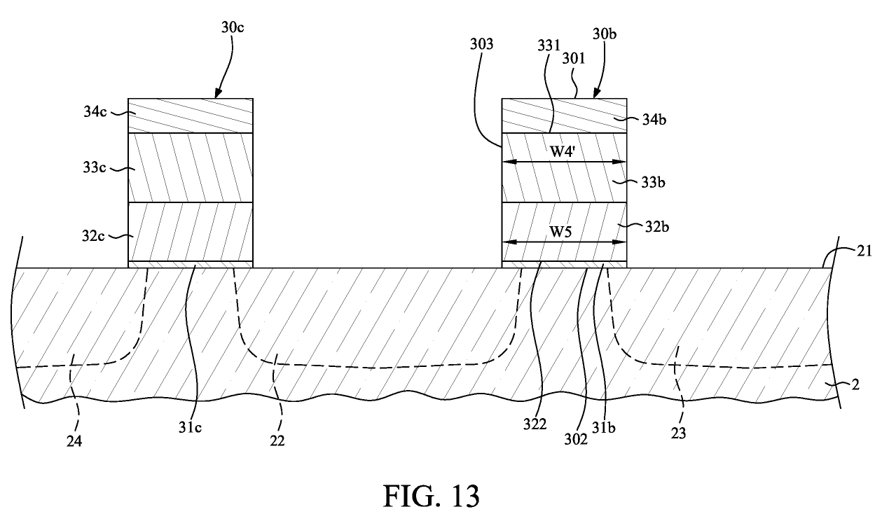

FIG. 13 to FIG. 16 illustrate stages of a method for manufacturing an electrical structure 1a in accordance with one embodiment of the present disclosure. The initial stage of the illustrated method is the same as, or similar to, the stage illustrated in FIG. 2. FIG. 13 illustrates a stage subsequent to the step of FIG. 2.

Referring to FIG. 13, a portion of the second gate conductor layer 33 and a portion of the first gate conductor layer 32 of FIG. 2 may be removed simultaneously by, for example, etching, so that the second gate conductor layer 33 of FIG. 2 may become a second gate conductor layer 33b of FIG. 13, and the first gate conductor layer 32 of FIG. 2 may become a first gate conductor layer 32b. The first gate conductor layer 32b may have a third width W5 that is substantially constant, and the second gate conductor layer 33b may have a fourth width W4' that is substantially constant. The fourth width W4' of the second gate conductor layer 33b may be substantially equal to the third width W5 of the first gate conductor layer 32b.

In addition, the width of the gate oxide layer 31b and the width of the upper layer 34b may be substantially equal to the third width W5 of the first gate conductor layer 32b. Thus, the first gate structure 30b may be in a single rectangular shape. The fourth width W4' of the second gate conductor layer 33b of FIG. 13 may be less than the second width W12 of FIG. 2. The third width W5 of the first gate conductor layer 32b of FIG. 13 may be less than the first width W11 of FIG. 2.

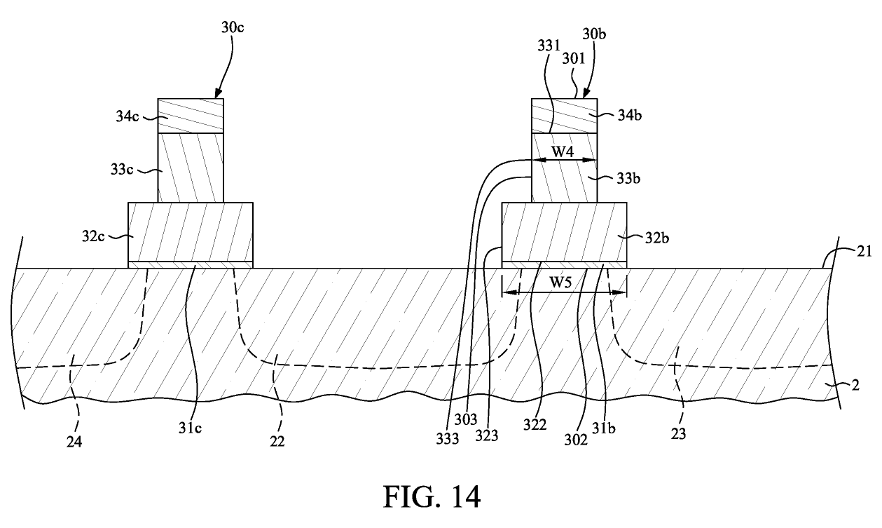

Referring to FIG. 14, a portion of the upper layer 34b and the second gate conductor layer 33b may be further removed by, for example, etching, so that the fourth width W4 of the second gate conductor layer 33b may be less than the third width W5 of the first gate conductor layer 32b. The fourth width W4 of the second gate conductor layer 33b may be substantially constant, and may be less than the fourth width W4' of FIG. 13. Thus, the first gate structure 30b may be formed. The first gate structure 30b may include a step structure.

Similarly, the profile of the second gate structure 30c may be the same as the profile of the first gate structure 30b. The second gate structure 30c may include a gate oxide layer 31c, a first gate conductor layer 32c, a second gate conductor layer 33c and an upper layer 34c which may be the same as the gate oxide layer 31b, the first gate conductor layer 32b, the second gate conductor layer 33b and the upper layer 34b of the first gate structure 30b, respectively.

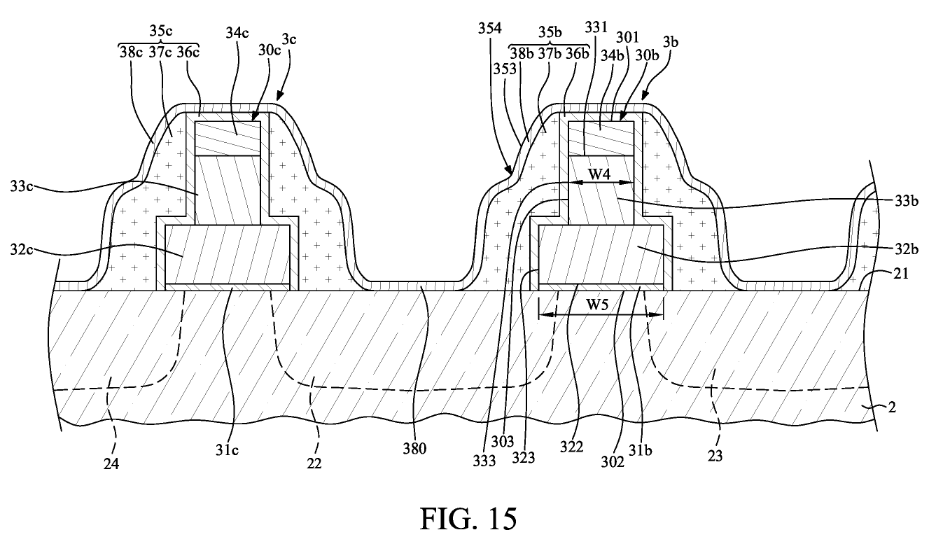

Referring to FIG. 15, a first layer 36b may be conformally formed or disposed on the lateral surface 303 of the first gate structure 30b. A first layer 36c may be conformally formed or disposed on the lateral surface of the second gate structure 30c. A material of the first layers 36b, 36c may include a nitride material. Then, a second layer 37b may be formed or disposed on a lateral surface of the first layer 36b and on a portion of the first surface 21 of the substrate 2. A second layer 37c may be formed or disposed on a lateral surface of the first layer 36c and on a portion of the first surface 21 of the substrate 2. The second layers 37b, 37c may taper upward, and may include an oxide material. For example, a lateral surface 353 of the first spacer 35b may include a concave portion 354 which corresponds to the step structure of the first gate structure 30b.

Then, a protection layer 380 may be formed on the first layers 36b, 36c and the second layers 37b, 37c by, for example, deposition. The protection layer 380 may include a nitride material. The protection layer 380 may include a third layer 38b on the second layer 37b of the first spacer 35b, and a third layer 38c on the second layer 37c of the second spacer 35c. Thus, the first spacer 35b may include the first layer 36b, the second layer 37b and the third layer 38b. The second spacer 35c may include the first layer 36c, the second layer 37c and the third layer 38c. Meanwhile, a first MOS transistor 3b and a second MOS transistor 3c may be formed and may be separated from each other. The first MOS transistor 3b may include the first gate structure 30b and the first spacer 35b disposed on the lateral surface 303 of the first gate structure 30b. The second MOS transistor 3c may include the second gate structure 30c and the second spacer 35c disposed on the lateral surface of the second gate structure 30c.

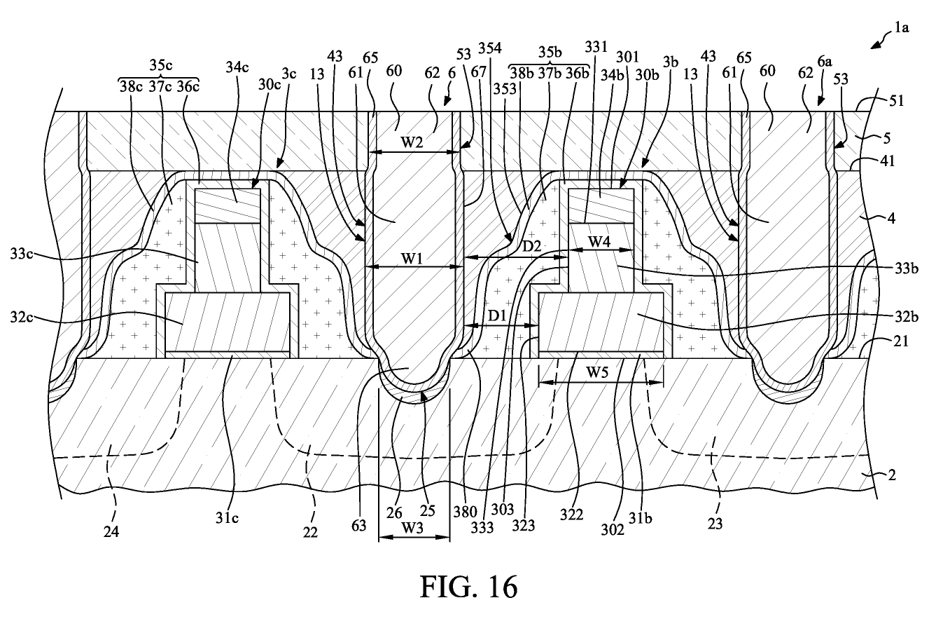

The initial stages of the illustrated method are the same as, or similar to, the stages illustrated in FIG. 5 to FIG. 12 so as to form the electrical structure 1a of FIG. 16.

FIG. 16 illustrates a schematic cross-sectional view of an electrical structure 1a in accordance with one embodiment of the present disclosure. The electrical structure 1a of FIG. 16 may be similar to the electrical structure 1 of FIG. 12, and the differences are described as follows.

In the electrical structure 1a, the first gate conductor layer 32b may have a substantially constant width W5. The second gate conductor layer 33b may have a substantially constant width W4. The substantially constant width W5 of the first gate conductor layer 32b may be greater than the substantially constant width W4 of the second gate conductor layer 33b. The lateral surface 333 of the second gate conductor layer 33b may be recessed from the lateral surface 323 of the first gate conductor layer 32b. Alternatively, the lateral surface 303 of the first gate structure 30b may have an upper portion 333 (e.g., the lateral surface 333 of the second gate conductor layer 33b) and a lower portion 323 (e.g., the lateral surface 323 of the first gate conductor layer 32b) substantially perpendicular to the first surface 21 of the substrate 2. The upper portion 333 (e.g., the lateral surface 333 of the second gate conductor layer 33b) of the lateral surface 303 may be recessed from the lower portion 323 (e.g., the lateral surface 323 of the first gate conductor layer 32b) of the lateral surface 303.

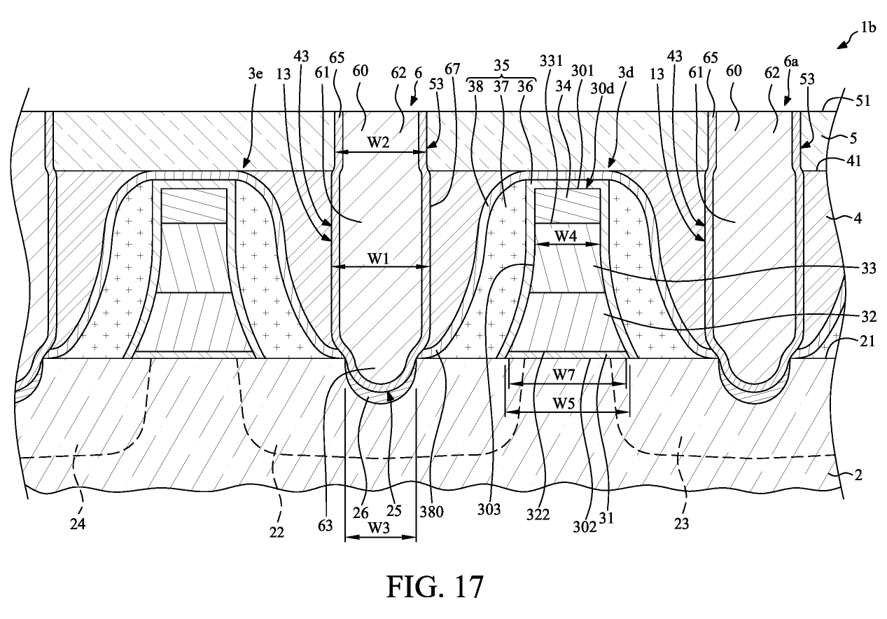

FIG. 17 illustrates a schematic cross-sectional view of an electrical structure 1b in accordance with one embodiment of the present disclosure. The electrical structure 1b of FIG. 17 may be similar to the electrical structure 1 of FIG. 12, except that the lateral surface 303 of the first gate structure 30d of the first MOS transistor 3d may be a concave surface or a curved surface. In addition, the structure of the second MOS transistor 3e may be the same as the structure of the first MOS transistor 3d.

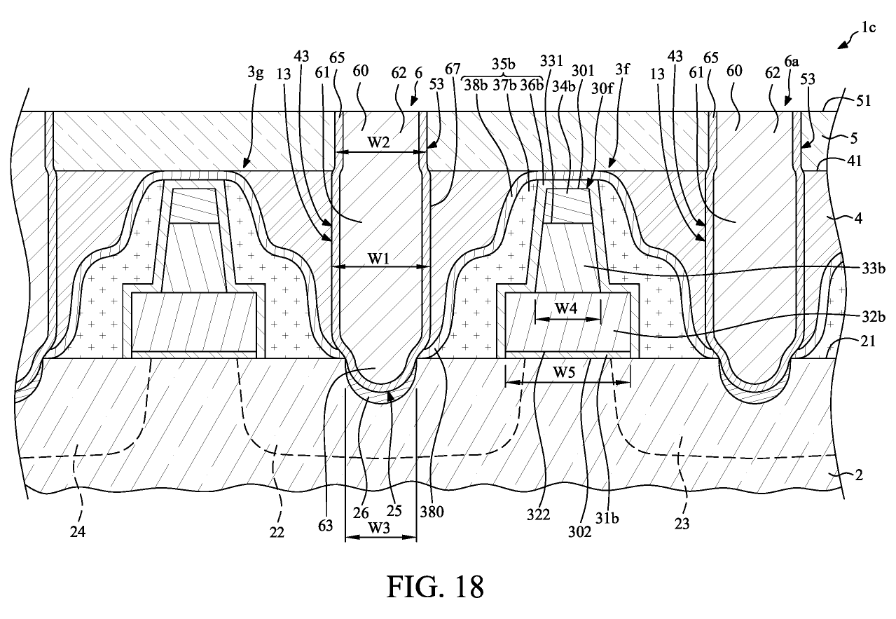

FIG. 18 illustrates a schematic cross-sectional view of an electrical structure 1c in accordance with one embodiment of the present disclosure. The electrical structure 1c of FIG. 18 may be similar to the electrical structure 1a of FIG. 16, except that the second gate conductor layer 33b and the upper layer 34b of the first gate structure 30f of the first MOS transistor 3f may taper away from the first gate conductor layer 32b of the first gate structure 30f of the first MOS transistor 3f. In addition, the structure of the second MOS transistor 3g may be the same as the structure of the first MOS transistor 3f.

One aspect of the present disclosure provides an electrical structure including a substrate and a metal-oxide-semiconductor (MOS) transistor. The MOS transistor is disposed on a first surface of the substrate, and includes a gate structure. The gate structure has a top surface and a bottom surface opposite to the top surface. A width of the top surface is less than a width of the bottom surface.

Another aspect of the present disclosure provides an electrical structure including a substrate, a MOS transistor and an electrical contact. The MOS transistor is disposed on a first surface of the substrate, and includes a gate structure. The electrical contact is disposed adjacent to the MOS transistor and electrically connects the first surface of the substrate. A distance between the gate structure of the MOS transistor and the electrical contact reduces toward the first surface of the substrate.

Another aspect of the present disclosure provides a method of manufacturing an electrical structure. The method includes forming a gate structure on a first surface of a substrate. The method also includes removing a portion of the gate structure, so that a width of a top surface of the gate structure is less than a width of a bottom surface of the gate structure. The method also includes forming a spacer on a lateral surface of the gate structure.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An electrical structure, comprising:
a substrate; and
a metal-oxide-semiconductor (MOS) transistor disposed on a first surface of the substrate, and including a gate structure having a top surface and a bottom surface opposite to the top surface, wherein a width of the top surface is less than a width of the bottom surface.

2. The electrical structure of claim 1, wherein the gate structure tapers away from the first surface of the substrate.

3. The electrical structure of claim 1, wherein a ratio of the width of the top surface to the width of the bottom surface is 1/4 to 1/2.

4. The electrical structure of claim 1, wherein the gate structure has a lateral surface extending between the top surface and the bottom surface, and the entire lateral surface is a flat inclined surface.

5. The electrical structure of claim 4, wherein the gate structure is in a trapezoid shape.

6. The electrical structure of claim 1, wherein the gate structure further has a lateral surface extending between the top surface and the bottom surface, and the lateral surface is a concave surface.

7. The electrical structure of claim 1, wherein the gate structure further has a lateral surface extending between the top surface and the bottom surface, wherein the lateral surface has an upper portion and a lower portion substantially perpendicular to the first surface of the substrate, and the upper portion of the lateral surface is recessed from the lower portion of the lateral surface.

8. The electrical structure of claim 1, wherein the gate structure includes a first gate conductor layer and a second gate conductor layer disposed on the first gate conductor layer, and a width of a top surface of the second gate conductor layer is less than a width of a bottom surface of the first gate conductor layer.

9. The electrical structure of claim 8, wherein both of the first gate conductor layer and the second gate conductor layer taper away from the first surface of the substrate, and a lateral surface of the first gate conductor layer is aligned with a lateral surface of the second gate conductor layer.

10. The electrical structure of claim 8, wherein the first gate conductor layer has a substantially constant width, the second gate conductor layer has a substantially constant width, and the substantially constant width of the first gate conductor layer is greater than the substantially constant width of the second gate conductor layer.

11. The electrical structure of claim 10, wherein a lateral surface of the second gate conductor layer is recessed from a lateral surface of the first gate conductor layer.

12. The electrical structure of claim 8, wherein the gate structure further includes a gate oxide layer disposed under the first gate conductor layer and an upper layer disposed on the second gate conductor layer.

13. The electrical structure of claim 12, wherein both of the gate oxide layer and the upper layer taper away from the first surface of the substrate.

14. The electrical structure of claim 12, wherein a bottom surface of the gate oxide layer is the bottom surface of the gate structure, and a top surface of the upper layer is the top surface of the gate structure.

15. The electrical structure of claim 1, wherein the MOS transistor further includes a spacer disposed on the gate structure.

16. The electrical structure of claim 15, wherein the spacer includes a first layer, a second layer and a third layer, wherein the first layer covers the gate structure, and includes a nitride material, wherein the second layer is disposed on the first layer, and includes an oxide material; wherein the third layer covers the second layer, and includes a nitride material.

17. The electrical structure of claim 15, wherein a lateral surface of the spacer includes a concave portion.

18. The electrical structure of claim 1, wherein the substrate includes silicon, the gate structure includes a first gate conductor layer and a second gate conductor layer, the first gate conductor layer includes a polysilicon material, the second gate conductor layer is disposed on the first gate conductor layer, and includes a tungsten material.

19. The electrical structure of claim 1, further comprising:
a first insulation layer disposed on the first surface of the substrate;
a second insulation layer disposed on the first insulation layer; and
an electrical contact extending through the first insulation layer and the second insulation layer to electrically connect the first surface of the substrate.

20. The electrical structure of claim 19, wherein the electrical contact includes a first portion disposed in the first insulation layer and a second portion disposed in the second insulation layer, wherein the first portion and the second portion of the electrical contact are formed integrally and concurrently.
